(19) United States
(12) Patent Application Publication
(10) Pub. No.: US 2025/0235902 A1
(43) Pub. Date: Jul. 24, 2025

(54) STAMP CLEANING DEVICE AND METHOD

(71) Applicant: Samsung Display Co., LTD., Yongin-si (KR)

(72) Inventor: Jeong Won HAN, Yongin-si (KR)

(21) Appl. No.: 18/903,127

(22) Filed: Oct. 1, 2024

(30) Foreign Application Priority Data
Jan. 22, 2024 (KR) 10-2024-0009346

(51) Int. Cl. B08B 7/00; H01L 21/67

(52) U.S. Cl. CPC B08B 7/0028; H01L 21/67144

(57) ABSTRACT

A stamp cleaning device and method using a stretching device are provided. a stamp cleaning device includes: a roll-to-roll unit including a first rolling portion and a second rolling portion, where the second rolling portion is disposed to be spaced apart from the first rolling portion, and configured to move an adhesive film from the first rolling portion to the second rolling portion; and a cleaning unit disposed between the first rolling portion and the second rolling portion, configured to stretch the adhesive film, and clean contaminants of a stamp by adhering the stretched adhesive film to the contaminants adhered to the stamp, where the roll-to-roll unit is configured to wind the adhesive film to which the contaminants are attached to the second rolling portion.

This application claims priority to Korean Patent Application No. 10-2024-0009346 filed on Jan. 22, 2024, and all the benefits accruing therefrom under 35 U.S.C. § 119, the content of which in its entirety is herein incorporated by reference.

### BACKGROUND

### 1. Field

The present disclosure relates to a stamp cleaning device and method using a stretching device.

### 2. Description of the Related Art

The importance of display devices is increasing with the development of multimedia. In response to this, various types of display devices such as organic light emitting display (OLED), liquid crystal display (LCD), etc. are being used.

As a device for displaying an image of a display device, it includes a display panel such as a light emitting display panel or a liquid crystal display panel. Among them, the light emitting display panel may include a light emitting diode (LED), such as an organic light emitting diode that utilizes an organic substance as a fluorescent material, or an inorganic light emitting diode that utilizes an inorganic substance as a fluorescent material.

In general, inorganic light emitting diodes are manufactured using an epi-growth method on a wafer. Inorganic light emitting diodes manufactured using the epi-growth method typically undergo a process of separating from the wafer and transferring them to another target substrate. In other words, transfer is a series of actions that transfer a single or multiple micro-LEDs to a target substrate.

The conventional method of transferring a single LED chip has been applied in the packaging process using pick and place equipment, but as the size of LED shrinks decreases to several microns, conventional pick and place equipment has limitations that make it difficult to keep up with the speed of work and precise transfer.

Currently, there are two main methods for transferring multiple micro-LEDs: direct transfer and printed transfer.

Direct transfer is a technology that directly bonds the material or thin film to be transferred to the target substrate, while printed transfer utilizes intermediate media such as electrostatic or bonding stamps.

In particular, continuously maintaining the adhesion of the stamp serves as a very important factor in transfer using a stamp transfer.

### SUMMARY

Aspects and features of embodiments of the present disclosure are to provide a device and method for easily removing a light emitting element or the like remaining on a stamp by transferring an adhesive film arranged so that the adhesive surface is on the upper surface in a roll-to-roll method.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an embodiment, a stamp cleaning device includes: a roll-to-roll unit including a first rolling portion and a second rolling portion, where the second rolling portion is disposed to be spaced apart from the first rolling portion, and configured to move an adhesive film from the first rolling portion to the second rolling portion; and a cleaning unit disposed between the first rolling portion and the second rolling portion, configured to stretch the adhesive film, and clean contaminants of a stamp by adhering the stretched adhesive film to the contaminants adhered to the stamp, where the roll-to-roll unit is configured to wind the adhesive film to which the contaminants are attached to the second rolling portion.

In an embodiment, the cleaning unit may include a support portion configured to support the adhesive film and a driving portion movable up and down, where the support portion may include a support chuck for fixing the adhesive film.

In an embodiment, the driving portion may include an upper driving portion and a lower driving portion, which are movable up and down, where the upper driving portion may move downward, and the lower driving portion may move upward to fix the adhesive film.

In an embodiment, the support portion may further include a vertical moving portion movable up and down, where the driving portion may be configured to fix the adhesive film, and the vertical moving portion may be configured to rise to stretch the adhesive film in a circumferential direction of the adhesive film.

In an embodiment, the driving portion may be configured to fix the adhesive film, and the roll-to-roll unit and the driving portion may be configured to move downward to stretch the adhesive film in a circumferential direction of the adhesive film.

In an embodiment, the first rolling portion may be configured to supply a laminated film in which a release paper is attached to the adhesive film, and the release paper may be disposed in an outer direction of the first rolling portion.

In an embodiment, the roll-to-roll unit may further include a third rolling portion configured to separate the release paper from the laminated film.

In an embodiment, the roll-to-roll unit may further include a first guide roller disposed between the first rolling portion and the cleaning unit and configured to guide the adhesive film and a second guide roller disposed between the second rolling portion and the cleaning unit and configured to guide the adhesive film.

In an embodiment, the upper driving portion may define an opening wider than an upper surface of the support portion in a plan view.

In an embodiment, the contaminant may include at least one of light emitting element and dust.

In an embodiment, the cleaning unit may have a roller shape and be movable up, down, left, and right.

In an embodiment, the cleaning unit may be configured to move in a direction in which the stamp is located and stretch the adhesive film in a circumferential direction of the adhesive film such that the adhesive film may adhere to the stamp.

In an embodiment, the cleaning unit may be configured to be attached to the stamp and move left and right.

In an embodiment, the first rolling portion, the second rolling portion, and the third rolling portion may be configured to rotate in the same direction.

According to an embodiment, a stamp cleaning method includes: supplying, by a roll-to-roll unit, an adhesive film onto a cleaning unit in a roll-to-roll manner; stretching, by the cleaning unit, the adhesive film; cleaning a stamp by adhering contaminants of the stamp to an adhesive surface of the adhesive film, and the collecting, by the roll-to-roll unit, the adhesive film to which the contaminants are adhered.

In an embodiment, the supplying of the adhesive film onto the cleaning unit may include separating a release paper from a laminated film wound on a first rolling portion by a third rolling portion to make the adhesive film, and transferring the adhesive film to a second rolling portion.

In an embodiment, the cleaning of the stamp may include: moving, by the cleaning unit, an upper driving portion downward and a lower driving portion upward to fix the adhesive film, stretching the adhesive film in a circumferential direction of the adhesive film by raising a support portion supporting the adhesive film upward, and holding, a support chuck on the support portion, the adhesive film to prevent the adhesive film from rising with the stamp during adhering the contaminants of the stamp to the adhesive surface of the adhesive film.

In an embodiment, the cleaning of the stamp may include: moving, by the cleaning unit, an upper driving portion downward and a lower driving portion upward to fix the adhesive film, moving the roll-to-roll unit, the upper driving portion, and the lower driving portion downward to stretch the adhesive film in a circumferential direction of the adhesive film, and holding, a support chuck on the support portion, the adhesive film to prevent the adhesive film from rising with the stamp during adhering the contaminants of the stamp to the adhesive surface of the adhesive film.

In an embodiment, the cleaning unit may be roller-shaped, and in the cleaning of the stamp, the cleaning unit may move up and down toward the stamp, contact the stamp, and move left and right on one surface of the stamp to clean the contaminants of the stamp.

In an embodiment, the method may further include: before the cleaning of the stamp, stopping operation of the roll-to-roll unit.

According to embodiments of the present disclosure, by removing the light emitting elements remaining in the stamp, the number of times the stamp may be used is increased, making it possible to increase the frequency of stamp replacement, thereby increasing product production time.

Furthermore, by attaching the adhesive film to the stamp without wrinkles in the adhesive film, stamp cleaning efficiency may be effectively increased.

However, the effects of the present disclosure are not limited to the aforementioned effects, and various other effects are included in the present specification.

### BRIEF DESCRIPTION OF THE DRAWINGS

FIG. 1 is a perspective view illustrating a configuration of a stamp cleaning device according to one embodiment.

FIG. 2 is a cross-sectional view taken along the dotted line in FIG. 1.

FIG. 3 is a perspective view to illustrate the structure of a laminated film.

FIG. 4 is a flowchart to illustrate a stamp cleaning method according to one embodiment.

FIGS. 5 to 11 are diagrams schematically illustrating one step of a stamp cleaning method according to one embodiment.

FIGS. 12 to 19 are diagrams schematically illustrating one step of a stamp cleaning method according to another embodiment.

FIG. 20 is a perspective view illustrating a configuration of a stamp cleaning device according to one embodiment.

FIG. 21 is a cross-sectional view taken along the dotted line in FIG. 20.

FIGS. 22 to 26 are diagrams schematically illustrating one step of a stamp cleaning method according to one embodiment.

FIG. 27 is a schematic diagram of a stamp cleaning device according to another embodiment.

FIG. 28 is a diagram to illustrate a method of operating the stamp cleaning device of FIG. 27.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, specific embodiments will be described with reference to the accompanying drawings.

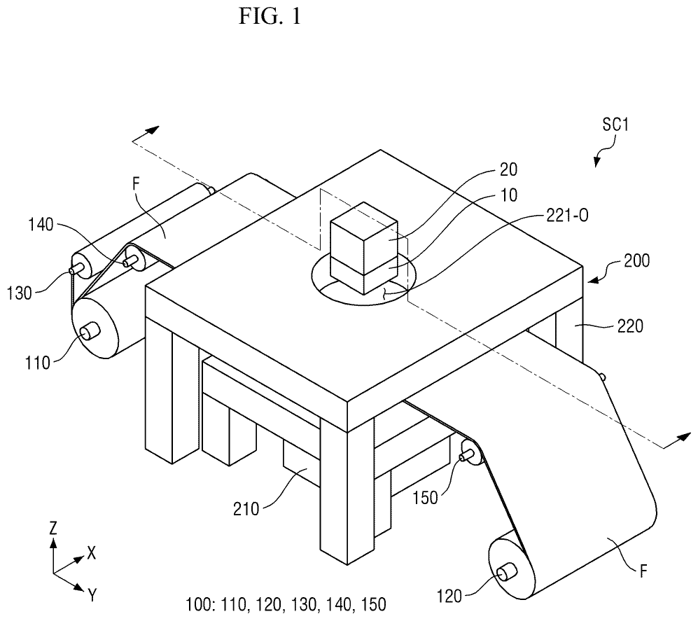

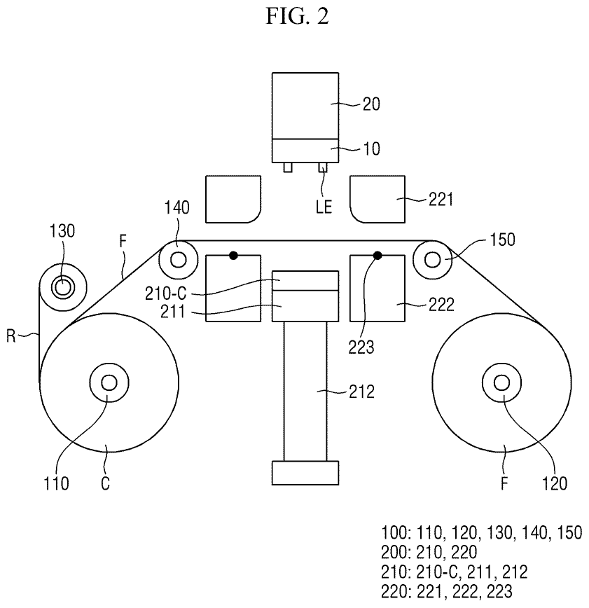

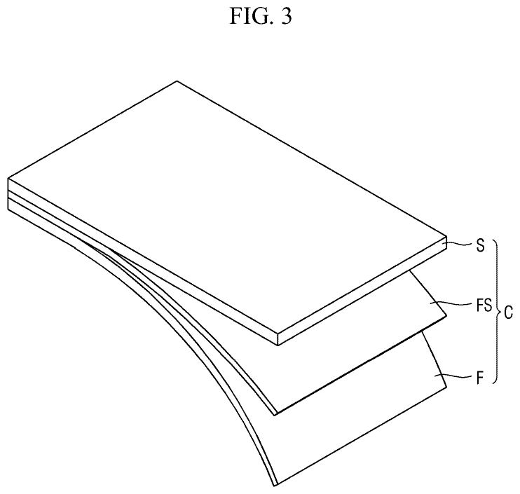

FIG. 1 is a perspective view illustrating a configuration of a stamp cleaning device according to one embodiment. FIG. 2 is a cross-sectional view taken along the dotted line in FIG. 1. FIG. 3 is a perspective view to illustrate the structure of a laminated film.

Referring to FIGS. 1 and 2, a stamp cleaning device SC1 is a device for removing a light emitting element LE attached to a stamp 10 and may include a roll-to-roll unit 100 and a cleaning unit 200.

The roll-to-roll unit 100 supplies the adhesive film F for bonding and removing the light emitting element LE attached to the stamp 10 in a roll-to-roll manner.

The roll-to-roll unit 100 may include a first rolling portion 110, a second rolling portion 120, and a third rolling portion 130. The first rolling portion 110 and the second rolling portion 120 may be disposed side by side, and the third rolling portion 130 may be disposed above the first rolling portion 110. The roll-to-roll unit 100 may further include a first guide roller 140 and a second guide roller 150.

Referring to FIG. 3, a laminated film C is composed of release paper R attached to the adhesive film F. The adhesive film F is a film with an adhesive agent S applied to one side, and the release paper R is disposed on the adhesive agent S to prevent foreign substances from adhering to the adhesive agent S.

The adhesive film F may be formed of a stretchable, elastic polymer material. The stretchable elastic polymer materials may include, for example, polyolefine, polyvinyl chloride (PVC), elastomeric silicone, elastomeric polyurethane, elastomeric polyisoprene, and the like.

The adhesive agent S may include one or more of, for example, urethane acrylate, epoxy acrylate, and polyester acrylate.

In the roll-to-roll unit 100, the first rolling portion 110, the second rolling portion 120, and the third rolling portion 130 may operate in synchronization with each other but are not limited thereto.

The first rolling portion 110 rotates in place in a unidirectional, e.g., clockwise direction to continuously unwind the pre-rolled laminated film C. The third rolling portion 130 rotates unidirectionally, for example clockwise, in place to wind only the release paper R from the laminated film C unwound from the first rolling portion 110. As a result, the release paper R is removed from the laminated film C by the roll-to-roll unit 100, and the adhesive agent S is exposed on the upper surface of the adhesive film F. One end of the adhesive film F is wound around the second rolling portion 120. The second rolling portion 120 rotates unidirectionally, for example clockwise, in place and continues to wind the adhesive film F unwound from the first rolling portion 110.

A cleaning unit 200 is disposed between the first rolling portion 110 and the second rolling portion 120. Accordingly, the adhesive film F, which is released from the first rolling portion 110 and has the adhesive agent S exposed on its upper surface, is continuously supplied to the cleaning unit 200.

The first guide roller 140 is disposed between the first rolling portion 110 and the cleaning unit 200 and guides and arranges the adhesive film F from the first rolling portion 110 to the cleaning unit 200.

The second guide roller 150 is disposed between the cleaning unit 200 and the second rolling portion 120 and guides and arranges the adhesive film F from the cleaning unit 200 to the second rolling portion 120.

The cleaning unit 200 may include a support portion 210 and a driving portion 220.

The support portion 210 may support the adhesive film F. The support portion 210 may include a support chuck 210-C. The support chuck 210-C may be any one of an electrostatic chuck, an adhesive chuck, a vacuum chuck, and a porous vacuum chuck. The support chuck 210-C may be fixed by adsorbing the back side of the adhesive film F disposed on the support portion 210.

In one embodiment, the support portion 210 may be capable of moving up and down. For example, the support portion 210 may include a support plate 211 and a vertical moving portion 212. The support plate 211 has a disk-shaped or polygonal panel-type upper surface. The adhesive film F may be disposed on the upper surface of the support plate 211.

The vertical moving portion 212 may be assembled on the back of the support plate 211, and the other side may be assembled with a pneumatic or hydraulic pressure regulator. Accordingly, the vertical moving portion 212 may move the support plate 211 in one direction or the other direction of the third direction by using a pneumatic or hydraulic pressure regulator.

The driving portion 220 may move up and down and may be disposed to surround the support portion 210. The driving portion 220 may include an upper driving portion 221 and a lower driving portion 222. Additionally, the driving portion 220 may further include a cushioning member 223.

The upper driving portion 221 may move up and down and may define an opening 221-O in the center. The size of the opening 221-O may be larger than the size of the stamp 10. Further, the size of the opening 221-O may be larger than the size of the support portion 210. That is, the opening 221-O may be wider than an upper surface 210U of the support portion 210 in a plan view.

The lower driving portion 222 is disposed below the upper driving portion 221 and is movable up and down. The lower driving portion 222 may move upward and the upper driving portion 221 may move downward, so that the upper driving portion 221 and the lower driving portion 222 may be in contact. The adhesive film F may be disposed on the lower driving portion 222, and when the lower driving portion 222 moves upward and the upper driving portion 221 moves downward, the adhesive film F may be fixed.

The cushioning member 223 may be disposed between the upper driving portion 231 and the lower driving portion 222. The cushioning member 223 may be formed of a resilient material to cushion the impact that occurs when the upper driving portion 231 and the lower driving portion 222 come into contact. For example, the cushioning member 223 may be an O-Ring.

According to one embodiment, the support portion 210 may be moved upward while the adhesive film F supplied by the roll-to-roll unit 100 is fixed in place by the upper driving portion 221 and the lower driving portion 222, thereby stretching the adhesive film F. When the adhesive film F is stretched, wrinkles of the adhesive film F may be removed. Therefore, when the adhesive film F is stretched and contacted with the lower surface of the stamp 10, all the light emitting elements LE and dust disposed on the lower surface of the stamp 10 may be removed.

In addition, according to one embodiment, during supplying the adhesive film F by the roll-to-roll unit 100, the adhesive surface FS of the adhesive film F does not directly contact each member, so that the adhesion of foreign substances to the adhesive surface FS of the adhesive film F may be minimized.

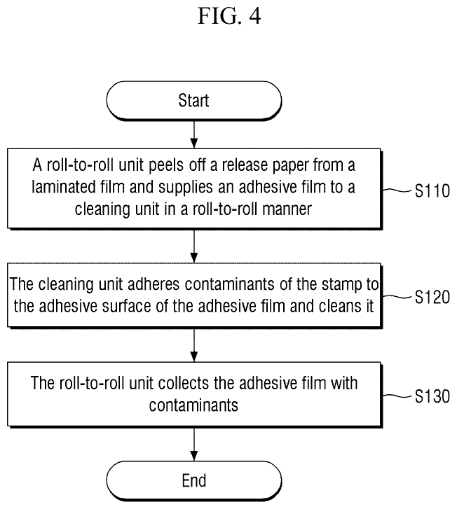

FIG. 4 is a flowchart to illustrate a stamp cleaning method according to one embodiment.

The method includes a step of the roll-to-roll unit to peel the release paper from the laminated film and supply the adhesive film F to the cleaning unit in a roll-to-roll manner (S110), a step of the cleaning unit to adhere the remaining material of the stamp to the adhesive surface of the adhesive film and support the adhesive film during cleaning (S121), and a step of the roll-to-roll unit to collect the adhesive film with residual material attached to the adhesive surface (S130).

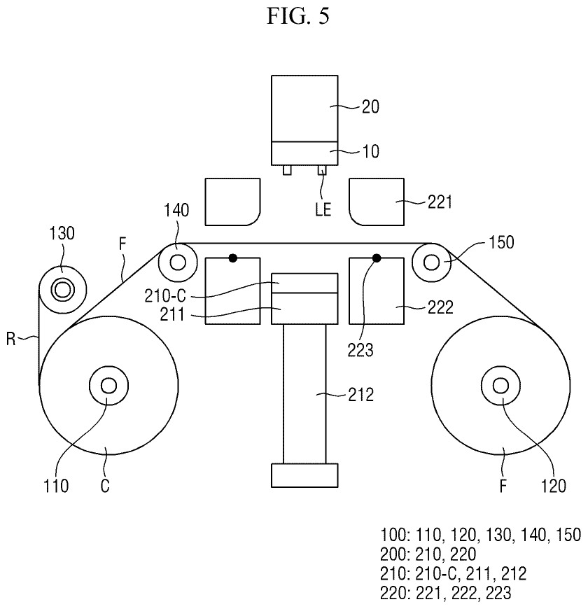

FIGS. 5 to 11 are diagrams schematically illustrating one step of a stamp cleaning method according to one embodiment. The stamp cleaning device of FIGS. 5 to 11 may correspond to the stamp cleaning device of FIG. 2.

Hereinafter, with reference to FIGS. 4 to 11, a stamp cleaning method according to one embodiment will be described.

First, referring to FIG. 5, the first rolling portion 110 of the roll-to-roll unit 100 peels the release paper R of the laminated film C from the adhesive film F and supplies the adhesive film F to the cleaning unit 200 in a roll-to-roll manner. (S110 in FIG. 4) For example, the laminated film C is wound on the first rolling portion 110 of the roll-to-roll unit 100, one end of the release paper R of the laminated film C is partially wound around the third rolling portion 130, and one end of the adhesive film F from which the release paper R has been peeled off is wound around the second rolling portion 120. In this state, when the first rolling portion 110 rotates in one direction, for example clockwise, the second rolling portion 120 and the third rolling portion 130 may rotate in synchronization. The second rolling portion 120 and the third rolling portion 130 may rotate in the same direction (clockwise) as the first rolling portion 110. In addition, the first guide roller 140 and the second guide roller 150 disposed between the first rolling portion 110 and the second rolling portion 120 also rotate in the same direction (clockwise) as the first rolling portion 110. Accordingly, the release paper R of the laminated film C is peeled off from the adhesive film F exposing the adhesive surface FS of the adhesive film F. In this way, the adhesive film F with the adhesive surface FS exposed is transferred to the cleaning unit 200 along the first guide roller 140. At this time, the first guide roller 140 disposed between the first rolling portion 110 and the cleaning unit 200 may assist in transporting the adhesive film F.

The laminated film C is arranged so that the adhesive film F is facing the first rolling portion 110 and the release paper R is facing the outside, and the third rolling portion 130 is arranged on the first rolling portion 110. Therefore, the adhesive film F from which the release paper R has been peeled off may maintain its adhesion by not contacting the adhesive surface FS of the adhesive film F with other units such as the guide roller while being transported to the cleaning unit 200.

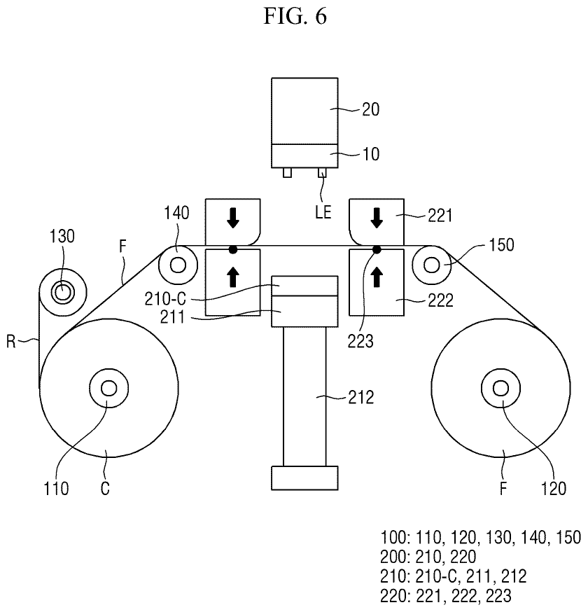

Next, referring to FIGS. 6 to 9, the cleaning unit 200 adheres the residual material of the stamp 10 to the adhesive surface of the adhesive film F and supports the adhesive film F during cleaning. (S120 in FIG. 4)

For example, referring to FIG. 6, the upper driving portion 221 and the lower driving portion 222 are moved up and down toward the adhesive film F to fix the adhesive film F. The upper driving portion 221 moves downward and the lower driving portion 222 moves upward and may be fixed by pressing the adhesive film F from above and below. The roll-to-roll unit 100 may stop operating while the adhesive film F is fixed by the upper driving portion 221 and the lower driving portion 222. After the roll-to-roll unit 100 stops operating, the upper driving portion 221 and the lower driving portion 222 may move.

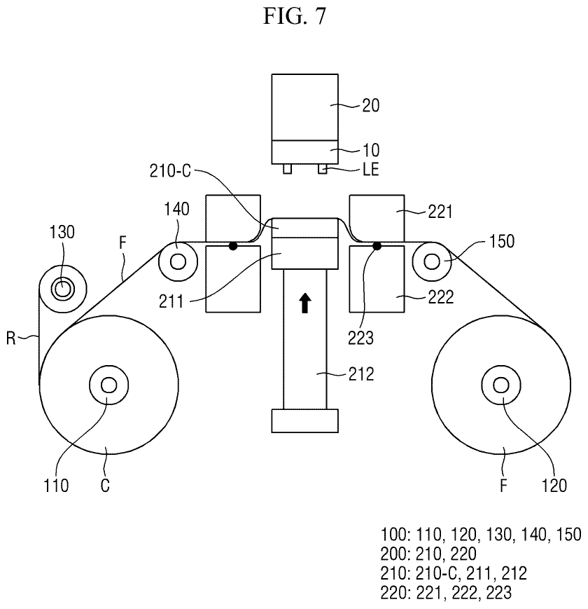

Referring to FIG. 7, the vertical moving portion 212 of the support portion 210 moves upward, so that the adhesive film F supported on the support plate 211 of the support portion 210 is pulled in the outer circumferential direction of the adhesive film F and stretched. Accordingly, wrinkles and the like that may have occurred in the adhesive film F are stretched out, and cleaning of the stamp 10 may be carried out effectively.

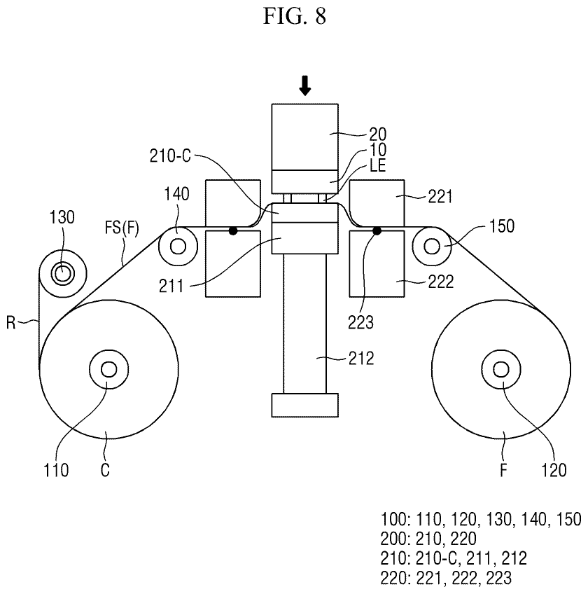

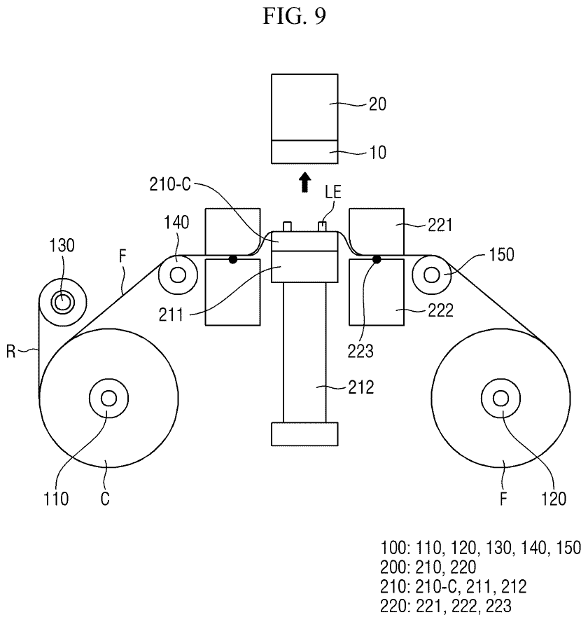

Referring to FIGS. 8 and 9, a stamp transfer head 20 moves the stamp 10. The stamp transfer head 20 moves the stamp 10 in a downward direction until it passes through an opening 221-O of the upper driving portion 221 and contacts the adhesive surface FS of the adhesive film F disposed on the support plate 211. Afterwards, the stamp transfer head 20 lifts the stamp 10.

At this time, the adhesive film F may be held on the upper portion of the support plate 211 using a support chuck 210-C so that the adhesive film F does not lift up along with the stamp 10.

In this process, the stamp cleaning device SC1 may clean the stamp 10 by peeling off contaminants such as the light emitting element LE residual on one side of the stamp 10 from one side of the stamp 10.

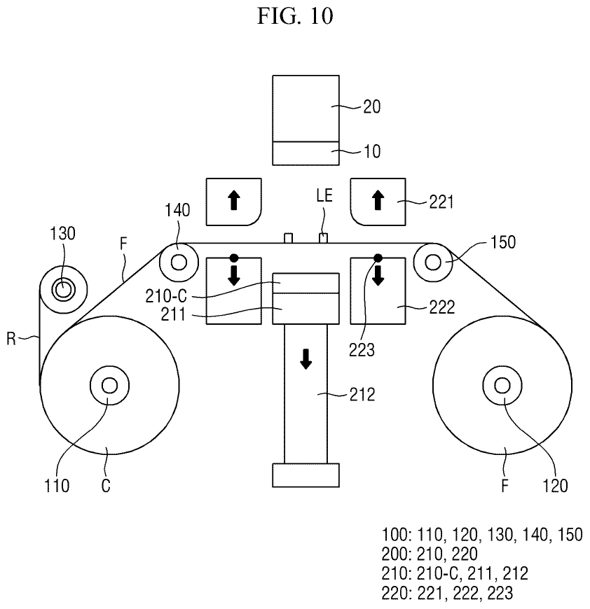

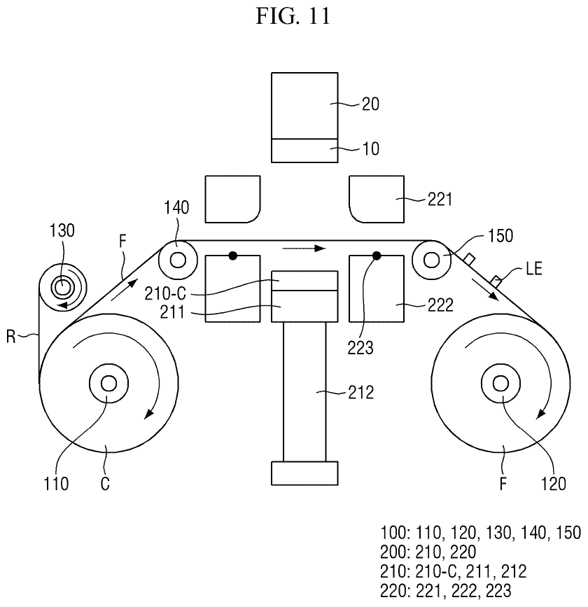

Referring to FIGS. 10 and 11, the roll-to-roll unit 100 collects the adhesive film with contaminants attached to the adhesive surface of the adhesive film F. (S130 in FIG. 4).

For example, referring to FIG. 10, the upper driving portion 221 and the lower driving portion 222 are moved up and down to release the adhesive film F. The upper driving portion 221 moves upward, and the lower driving portion 222 moves downward to unfasten the adhesive film F. In addition, the chuck function of the support chuck 210-C on the upper portion of the support plate 211 is released, and the vertical moving portion 212 is moved downward to enable the adhesive film F to be transferred.

Next, referring to FIG. 11, the first rolling portion 110, the second rolling portion 120, the third rolling portion 130, the first guide roller 140, and the second guide roller 150 are moved in one direction. Accordingly, the adhesive film F to which contaminants are attached is collected by being wound around the second rolling portion 120.

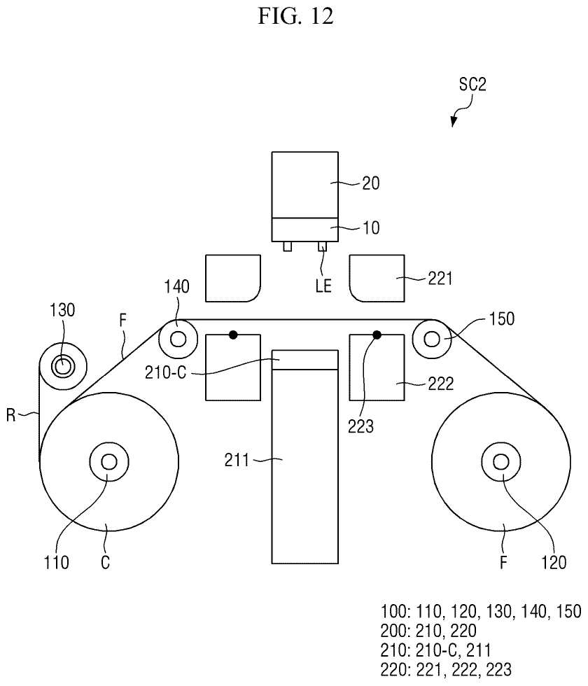

FIGS. 12 to 19 are diagrams schematically illustrating one step of a stamp cleaning method according to another embodiment.

FIG. 12 is a cross-sectional view taken along the dotted line in FIG. 1 according to another embodiment. FIG. 12 is different from FIG. 2 in that the cleaning unit 200 does not move up and down, but the roll-to-roll unit 100 may move up and down. Also, the cleaning unit 200 is different from the stamp cleaning device SC1 of FIG. 2 in that the cleaning unit 200 includes a support plate 211 and a support chuck 210-C and does not include a vertical transfer portion.

Referring to FIG. 12, the first rolling portion 110 of the roll-to-roll unit 100 peels off the release paper R of the laminated film C from the adhesive film F supplies the adhesive film F to the cleaning unit 200 in a roll-to-roll manner. Since the supply operation has been described with reference to FIG. 5, detailed description will be omitted.

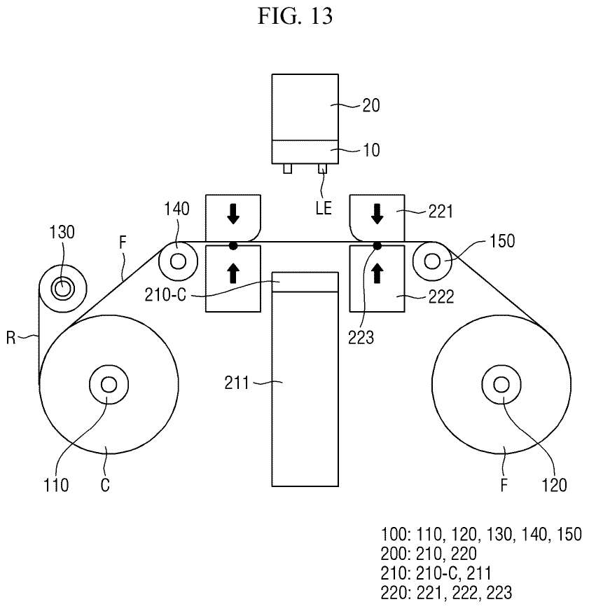

Next, referring to FIGS. 13 to 16, the cleaning unit 200 adheres the residual material of the stamp 10 to the adhesive surface of the adhesive film F and supports the adhesive film F during cleaning. (S120 in FIG. 4)

For example, referring to 13, the upper driving portion 221 and the lower driving portion 222 are moved up and down toward the adhesive film F to fix the adhesive film F. The upper driving portion 221 moves downward and the lower driving portion 222 moves upward and may be fixed by pressing the adhesive film F from above and below. The roll-to-roll unit 100 may stop operating while the adhesive film F is fixed by the upper driving portion 221 and the lower driving portion 222. After the roll-to-roll unit 100 stops operating, the upper driving portion 221 and the lower driving portion 222 may move.

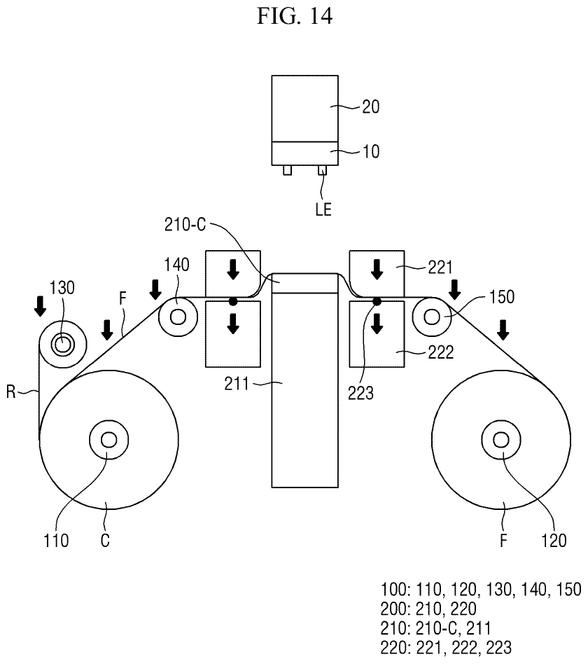

Referring to FIG. 14, the driving portion 220 and the roll-to-roll unit 100 move downward so that the adhesive film F supported on the support plate 211 of the support portion 210 is pulled in the outer circumferential direction of the adhesive film F and stretched. Accordingly, wrinkles that may have occurred in the adhesive film F are stretched out, and cleaning of the stamp 10 may be carried out effectively.

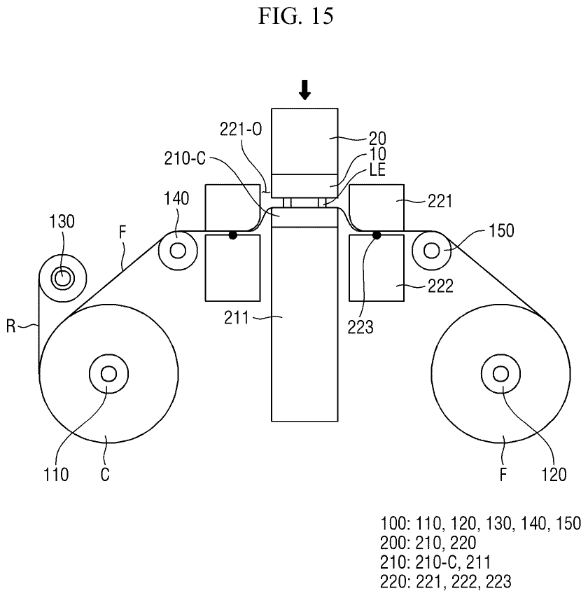

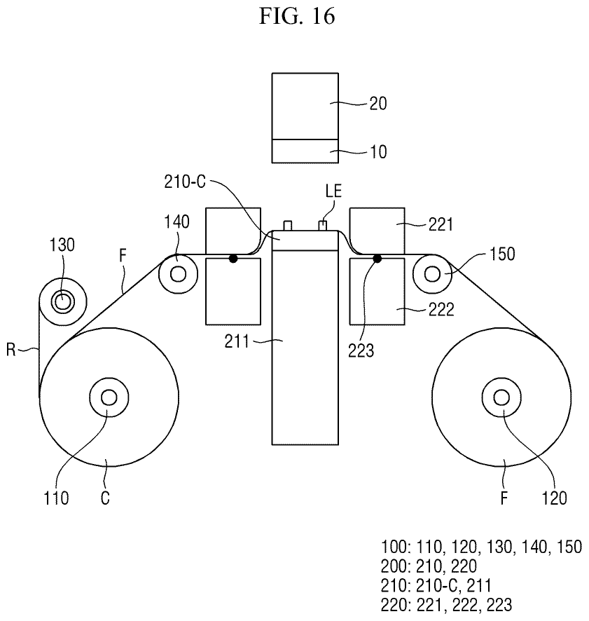

Referring to FIGS. 15 and 16, a stamp transfer head 20 moves the stamp 10. The stamp transfer head 20 moves the stamp 10 in a downward direction until it passes through an opening 221-O of the upper driving portion 221 and contacts the adhesive surface FS of the adhesive film F disposed on the support plate 211. Afterwards, the stamp transfer head 20 lifts the stamp 10. At this time, the adhesive film F may be held on the upper portion of the support plate 211 using a support chuck 210-C so that the adhesive film F does not lift up along with the stamp 10.

In this process, the stamp cleaning device SC1 may clean the stamp 10 by peeling off contaminants such as the light emitting element LE residual on one side of the stamp 10 from one side of the stamp 10.

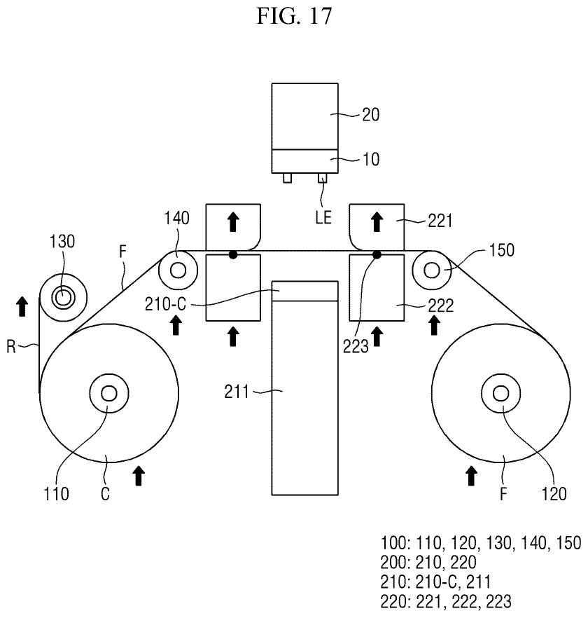

Thereafter, referring to FIGS. 17 to 19, the roll-to-roll unit 100 collects the adhesive film with contaminants attached to the adhesive surface FS of the adhesive film F. (S130 in FIG. 4).

For example, referring to FIG. 17, the driving portion 220 and the roll-to-roll unit 100 move upward and return to their original positions.

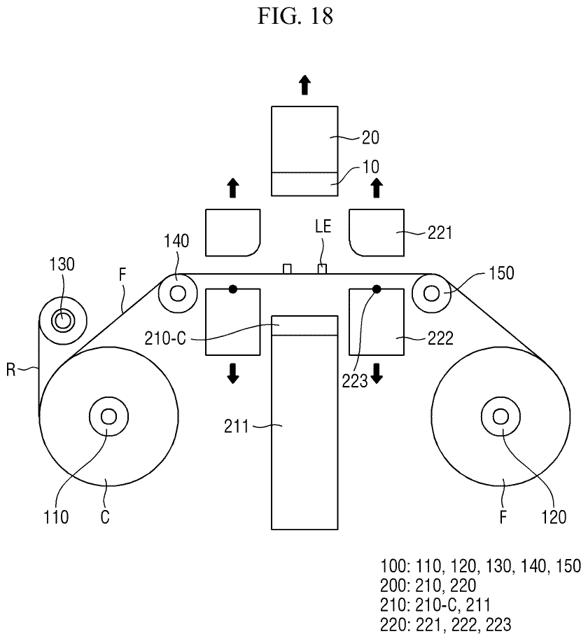

Thereafter, referring to FIG. 18, the upper driving portion 221 and the lower driving portion 222 are moved up and down to release the fixation of the adhesive film F. Since the unfastening of the adhesive film F has been described with reference to FIG. 10, detailed description will be omitted.

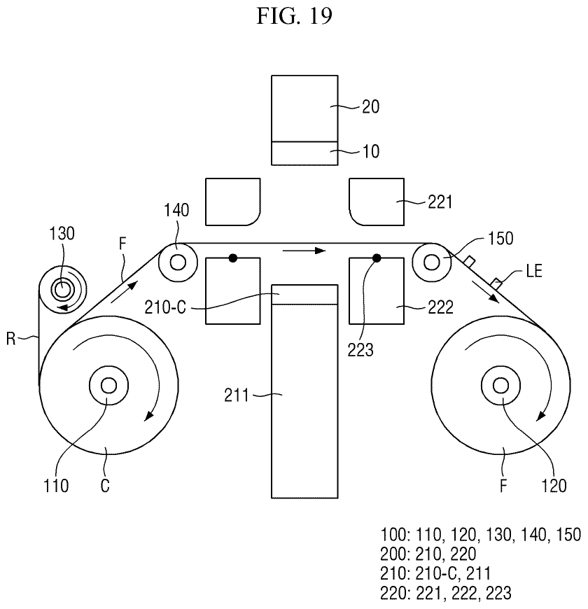

Next, referring to FIG. 19, the first rolling portion 110, the second rolling portion 120, the third rolling portion 130, the first guide roller 140, and the second guide roller 150 are moved in one direction. Accordingly, the adhesive film F to which contaminants are attached is collected by being wound around the second rolling portion 120.

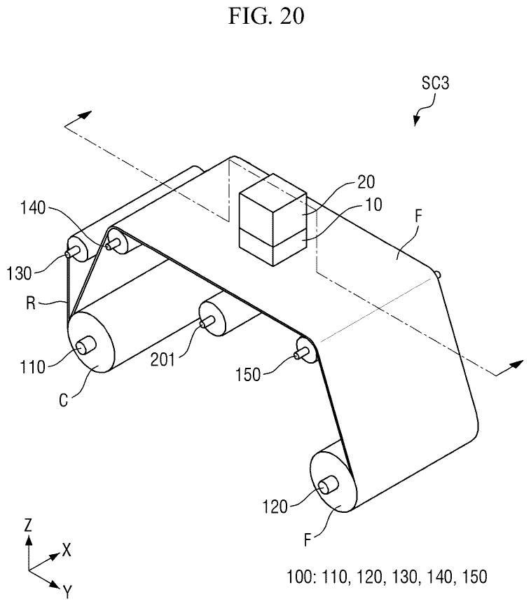

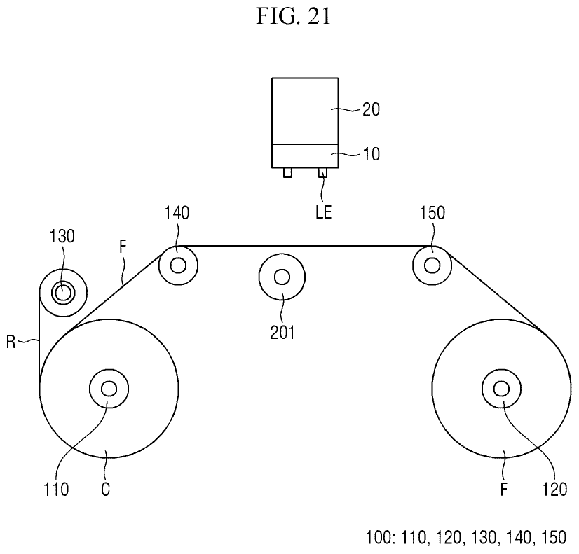

FIG. 20 is a perspective view illustrating a configuration of a stamp cleaning device according to one embodiment. FIG. 21 is a cross-sectional view taken along the dotted line in FIG. 20.

Referring to FIGS. 20 and 21, the stamp cleaning device SC2 is a device for removing the light emitting element LE or the like attached to the stamp 10 and may include a roll-to-roll unit 100 and a cleaning unit 201.

FIGS. 20 and 21 differ from the stamp cleaning device SC1 of FIGS. 1 and 2 in that the cleaning unit 201 has a roller shape rather than a stage shape, and the embodiments of FIGS. 20 and 21 omit descriptions that are redundant with the embodiments of FIGS. 1 and 2.

The roll-to-roll unit 100 supplies the adhesive film F for attaching and separating the light emitting element LE attached to the stamp 10 in a roll-to-roll manner.

The cleaning unit 201 is disposed between the first guide roller 140 and the second guide roller 150.

The cleaning unit 201 is movable up, down, left, and right. The operation of the cleaning unit 201 will be described in detail with reference to FIGS. 4, 22, and 24.

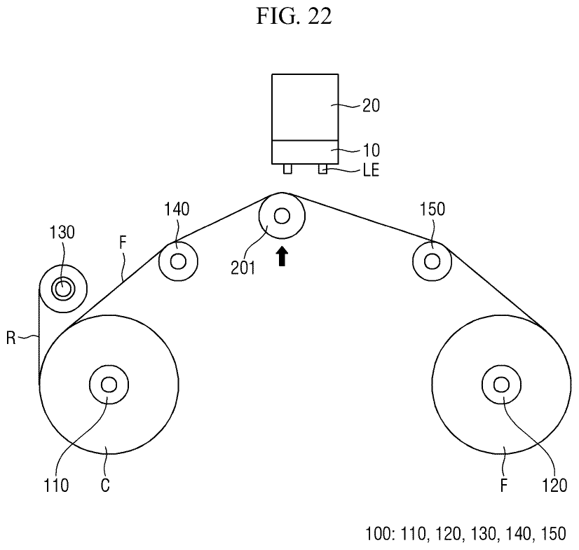

FIGS. 22 to 26 are diagrams schematically illustrating one step of a stamp cleaning method according to one embodiment. The stamp cleaning device of FIGS. 22 to 26 may correspond to the stamp cleaning device of FIG. 21.

Hereinafter, with reference to FIGS. 4 and FIGS. 21 to 24, a stamp cleaning method according to one embodiment will be described.

First, referring to FIG. 21, the roll-to-roll unit 100 peels off the release paper R from the laminated film C and supplies the adhesive film F to the cleaning unit 201 in a roll-to-roll manner. (S110 in FIG. 4) Since the method of supplying the adhesive film F has been described with reference to FIG. 4, a detailed description will be omitted.

Referring to FIGS. 22 to 25, the cleaning unit 201 cleans the adhesive film F by adhering the residual material of the stamp to the adhesive surface FS of the adhesive film F. (S120 of FIG. 4)

Referring to FIG. 22, the adhesive film F is stretched by moving the cleaning unit 201 upward (in the direction in which the stamp is located). Accordingly, the adhesive film F is stretched to remove any wrinkles that may have occurred in the adhesive film F, and the stamp 10 may be cleaned effectively.

The roll-to-roll unit 100 may stop operating while the cleaning unit 201 is operating. For example, the cleaning unit 201 may move after the roll-to-roll unit 100 stops operating.

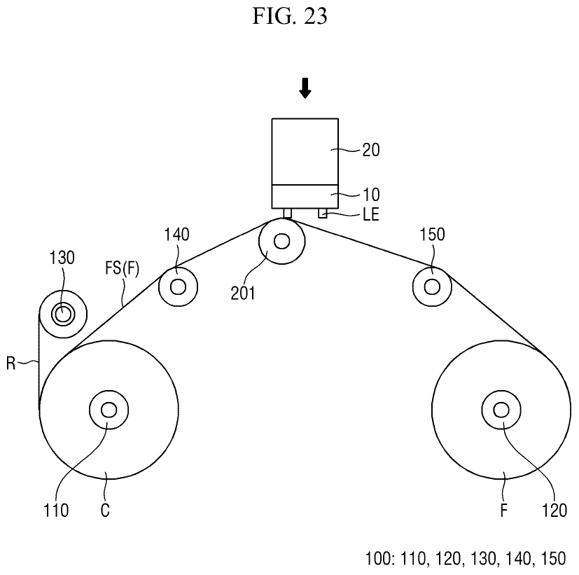

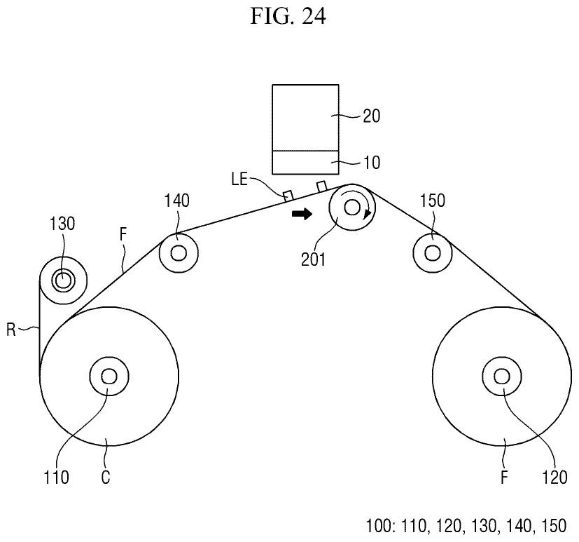

Referring to FIGS. 23 and 24, the stamp transfer head 20 moves the stamp 10 in a downward direction until it contacts the adhesive surface FS of the adhesive film F disposed on the cleaning unit 201. Thereafter, the cleaning unit 201 is moved in the horizontal direction (e.g., toward the second rolling portion 120). By rotating the roller-type cleaning unit 201 in one direction, the adhesive surface FS of the adhesive film F is adhered to the entire surface of the stamp 10. Accordingly, contaminants on the entire first surface of the stamp 10 can be cleaned.

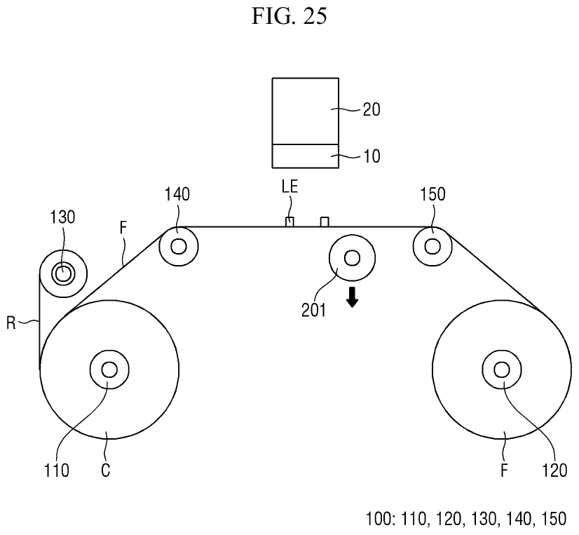

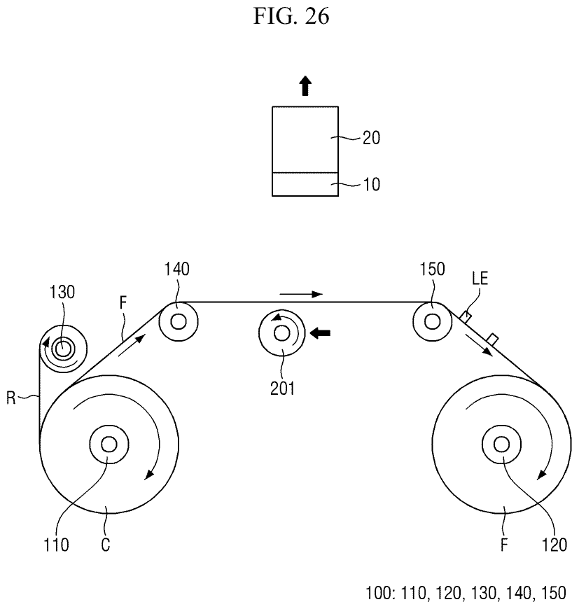

Referring to FIGS. 25 and 26, the roll-to-roll unit 100 collects the adhesive film with contaminants attached to the adhesive surface of the adhesive film F. (S130 in FIG. 4).

For example, referring to FIG. 25, the cleaning unit 201 is moved downward.

Next, referring to FIG. 26, the first rolling portion 110, the second rolling portion 120, the first guide roller 140, and the second guide roller 150 are rotated in one direction (clockwise) and the third rolling portion 130 is rotated in the opposite direction (counterclockwise). Accordingly, the adhesive film F with the contaminant attached is wound on the second rolling portion 120 and collected. Furthermore, the cleaning unit 201 is moved in the horizontal direction (for example, toward the first rolling portion 110) and positioned in place.

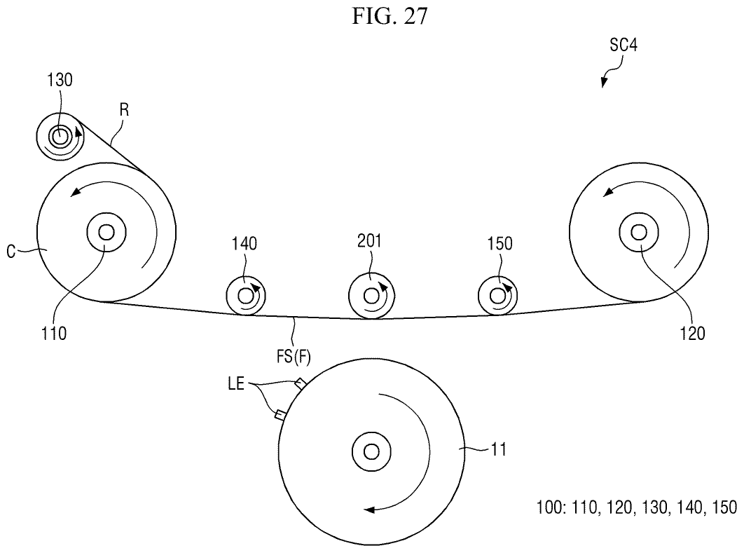

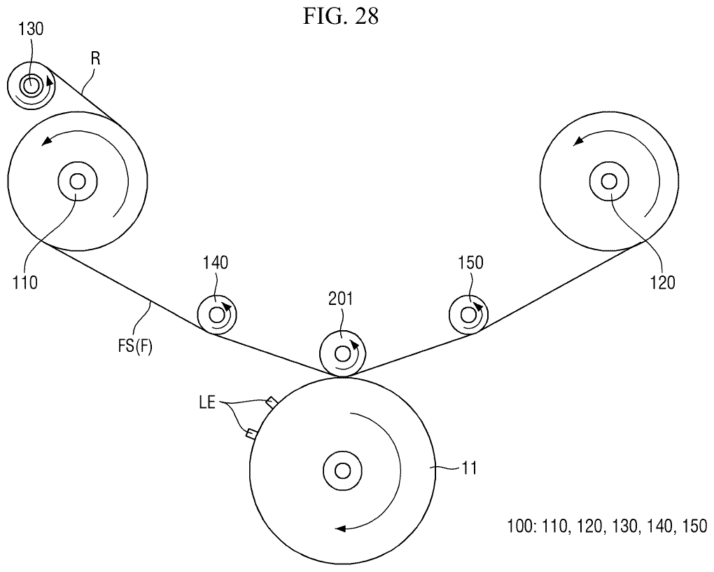

FIG. 27 is a schematic diagram of a stamp cleaning device according to another embodiment and FIG. 28 is a diagram to illustrate a method of operating the stamp cleaning device of FIG. 27. The stamp cleaning device SC4 of FIG. 27 differs from the stamp cleaning device SC3 of FIGS. 20 and 21 in that the first guide roller 140, the second guide roller 150, and the cleaning unit 201 are arranged on the adhesive film F to be applied to the cleaning device SC4 of a roller-type stamp 11.

Referring to FIGS. 27 and 28, since the roller-type stamp 11 is disposed below the stamp cleaning device SC4, the stamp cleaning device SC4 is disposed with the adhesive surface FS of the adhesive film F facing the lower surface. Furthermore, the cleaning unit 201 also moves downward and comes into contact with the roller-type stamp 11. Other operations are similar to those of the stamp cleaning device SC3 described with reference to FIGS. 20 to 26.

As described in one embodiment, the stamp cleaning devices SC1 to SC4 remove contaminants such as light emitting elements remaining on the stamps 10 and 11, enabling an increase in the number of times the stamps 10, 11 may be used. As a result, the replacement cycle of the stamps 10 and 11 may be increased, thereby increasing product production time.

In addition, by stretching the adhesive film F before adhering the adhesive film F to the stamps 10 and 11, wrinkles that may occur on the adhesive film F may be removed, thereby increasing the efficiency of cleaning the stamp.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A stamp cleaning device comprising:
a roll-to-roll unit including a first rolling portion and a second rolling portion, wherein the second rolling portion is disposed to be spaced apart from the first rolling portion, and configured to move an adhesive film from the first rolling portion to the second rolling portion; and
a cleaning unit disposed between the first rolling portion and the second rolling portion, configured to stretch the adhesive film, and clean contaminants of a stamp by adhering the stretched adhesive film to the contaminants adhered to the stamp,
wherein the roll-to-roll unit is configured to wind the adhesive film to which the contaminants are attached to the second rolling portion.

2. The stamp cleaning device of claim 1, wherein the cleaning unit includes a support portion configured to support the adhesive film and a driving portion movable up and down,
wherein the support portion includes a support chuck for fixing the adhesive film.

3. The stamp cleaning device of claim 2, wherein the driving portion includes an upper driving portion and a lower driving portion, which are movable up and down,
wherein the upper driving portion moves downward, and the lower driving portion moves upward to fix the adhesive film.

4. The stamp cleaning device of claim 3, wherein the support portion further includes a vertical moving portion movable up and down,
wherein the driving portion is configured to fix the adhesive film, and the vertical moving portion is configured to rise to stretch the adhesive film in a circumferential direction of the adhesive film.

5. The stamp cleaning device of claim 3, wherein the driving portion is configured to fix the adhesive film, and the roll-to-roll unit and the driving portion are configured to move downward to stretch the adhesive film in a circumferential direction of the adhesive film.

6. The stamp cleaning device of claim 1, wherein the first rolling portion is configured to supply a laminated film in which a release paper is attached to the adhesive film, and the release paper is disposed in an outer direction of the first rolling portion.

7. The stamp cleaning device of claim 6, wherein the roll-to-roll unit further comprises a third rolling portion configured to separate the release paper from the laminated film.

8. The stamp cleaning device of claim 1, wherein the roll-to-roll unit further comprises a first guide roller disposed between the first rolling portion and the cleaning unit and configured to guide the adhesive film and a second guide roller disposed between the second rolling portion and the cleaning unit and configured to guide the adhesive film.

9. The stamp cleaning device of claim 3, wherein the upper driving portion defines an opening wider than an upper surface of the support portion in a plan view.

10. The stamp cleaning device of claim 1, wherein the contaminant includes at least one of light emitting element and dust.

11. The stamp cleaning device of claim 1, wherein the cleaning unit has a roller shape and is movable up, down, left, and right.

12. The stamp cleaning device of claim 11, wherein the cleaning unit is configured to move in a direction in which the stamp is located and stretch the adhesive film in a circumferential direction of the adhesive film such that the adhesive film adheres to the stamp.

13. The stamp cleaning device of claim 12, wherein the cleaning unit is configured to be attached to the stamp and move left and right.

14. The stamp cleaning device of claim 7, wherein the first rolling portion, the second rolling portion, and the third rolling portion are configured to rotate in a same direction.

15. A stamp cleaning method comprising:
supplying, by a roll-to-roll unit, an adhesive film onto a cleaning unit in a roll-to-roll manner;
stretching, by the cleaning unit, the adhesive film;
cleaning a stamp by adhering contaminants of the stamp to an adhesive surface of the adhesive film; and
collecting, by the roll-to-roll unit, the adhesive film to which the contaminants are adhered.

16. The method of claim 15, wherein the supplying of the adhesive film onto the cleaning unit comprises:
separating a release paper from a laminated film wound on a first rolling portion by a third rolling portion to make the adhesive film, and transferring the adhesive film to a second rolling portion.

17. The method of claim 16, wherein the cleaning of the stamp comprises:
moving, by the cleaning unit, an upper driving portion downward and a lower driving portion upward to fix the adhesive film,
stretching the adhesive film in a circumferential direction of the adhesive film by raising a support portion supporting the adhesive film upward, and
holding, a support chuck on the support portion, the adhesive film to prevent the adhesive film from rising with the stamp during adhering the contaminants of the stamp to the adhesive surface of the adhesive film.

18. The method of claim 15, wherein the cleaning of the stamp comprises:
moving, by the cleaning unit, an upper driving portion downward and a lower driving portion upward to fix the adhesive film,
moving the roll-to-roll unit, the upper driving portion, and the lower driving portion downward to stretch the adhesive film in a circumferential direction of the adhesive film, and
holding, a support chuck on the support portion, the adhesive film to prevent the adhesive film from rising with the stamp during adhering the contaminants of the stamp to the adhesive surface of the adhesive film.

19. The method of claim 15, wherein the cleaning unit is roller-shaped, and
wherein, in the cleaning of the stamp, the cleaning unit moves up and down toward the stamp, contacts the stamp, and moves left and right on one surface of the stamp to clean the contaminants of the stamp.

20. The method of claim 15, further comprising:
before the cleaning of the stamp,
stopping operation of the roll-to-roll unit.
